(19) United States
(12) Patent Application Publication
(10) Pub. No.: US 2012/0228588 A1
(43) Pub. Date: Sep. 13, 2012

(54) LIGHT-EMITTING ELEMENT, LIGHT-EMITTING DEVICE, DISPLAY DEVICE, AND ELECTRONIC APPARATUS

(75) Inventor: Masayuki MITSUYA, Chino-shi (JP)

(73) Assignee: SEIKO EPSON CORPORATION, Tokyo (JP)

(21) Appl. No.: 13/410,651

(22) Filed: Mar. 2, 2012

(30) Foreign Application Priority Data
Mar. 7, 2011 (JP) 2011-049643

(51) Int. Cl. H01L 51/54

(52) U.S. Cl. 257/40; 257/E51.026

(57) ABSTRACT

A light-emitting element includes an anode, a cathode, a luminescent layer between the anode and the cathode that emits light by applying a current between the anode and the cathode, and an electron transport layer between the cathode and the luminescent layer that transports electrons from the cathode to the luminescent layer. The electron transport layer includes an n-type transport layer and a buffer layer in contact with the n-type electron transport layer. The n-type electron transport layer contains a first electron transport material and an electron donor material and is disposed to the cathode side of the buffer layer. The buffer layer contains a second electron transport material and is disposed to the luminescent layer side of the n-type electron transport layer so as to prevent the electron injection material from diffusing from the n-type electron transport layer to the luminescent layer.

### BACKGROUND

1. Technical Field

The present invention relates to a light-emitting element, a light-emitting device, a display device and an electronic apparatus.

2. Related Art

An organic electroluminescent element (organic EL element) is a type of light-emitting element and has a structure including at least one light-emitting organic layer between an anode and a cathode. In this type of light-emitting element, electrons and holes are injected to the light-emitting organic layer or luminescent layer respectively from the cathode and the anode by applying an electric field between the cathode and the anode, and the electrons and the holes are recombined to each other to form excitons in the luminescent layer. When the excitons return to the ground state, the energy is emitted as light.

For example, a light-emitting element of this type includes an n-type electron transport layer containing an electron transport material and an electron donor material as an electron transport layer between a cathode and a luminescent layer (for example, JP-A-10-270171).

in this light-emitting element, the electron donor material in the n-type electron transport layer facilitates the transport of electrons from the cathode to the n-type electron transport layer, and the electron transport material can receive electrons from the electron donor material and thus come into a radical state. Consequently, the light-emitting element can be operated at a low voltage.

However, if the light-emitting element including the n-type electron transport layer is continuously operated at a constant current, the electron donor material in the n-type electron transport layer diffuses into the adjacent luminescent layer with time, consequently undesirably reducing the luminance lifetime of the light-emitting element.

### SUMMARY

An advantage of some aspects of the invention is that it provides a light-emitting element that can be operated at a low voltage and exhibit a long life, and also provides a light-emitting device, a display device and an electronic apparatus each including the light-emitting element.

According to an aspect of the invention, a light-emitting element is provided which includes an anode, a cathode, a luminescent layer between the anode and the cathode that emits light by applying a current between the anode and the cathode, and an electron transport layer between the cathode and the luminescent layer that transports electrons from the cathode to the luminescent layer. The electron transport layer includes an n-type transport layer and a buffer layer in contact with the n-type electron transport layer. The n-type electron transport layer contains a first electron transport material and an electron donor material and is disposed to the cathode side of the buffer layer. The buffer layer contains a second electron transport material and is disposed to the luminescent layer side of the n-type electron transport layer so as to prevent the electron donor material from diffusing from the n-type electron transport layer to the luminescent layer.

Since the electron donor material in the n-type electron transport layer can be reliably prevented from diffusing into the luminescent layer, the light-emitting element can exhibit a long life.

Preferably, the first electron transport material and the second electron transport material are such a combination as the electron donor material is less diffusible in the buffer layer than in the n-type electron transport layer.

Thus, the electron donor material, or electron injection material, can be confined in the n-type electron transport layer effectively.

Preferably, the first electron transport material has a higher electron mobility than the second electron transport material.

Thus, the driving voltage can be maintained relatively low.

Preferably, the first electron transport material is an organic compound not containing a metal, and the second electron transport material is an organic metal complex.

Thus, both the diffusion of the electron donor material to the luminescent layer and the increase in the driving voltage of the light-emitting element can be reduced or prevented with reliability.

Preferably, the electron donor material is at least one substance selected from the group consisting of alkali metals, alkaline-earth metals, alkali metal compounds, and alkaline-earth metal compounds.

These electron donor materials have high ability to inject electrons. Accordingly, electrons supplied from the cathode can be efficiently injected to the luminescent layer.

Preferably, the buffer layer has an average thickness in the range of 3.0 to 20.0 nm.

Thus, the electron donor material can be reliably prevented from diffusing from the n-type electron transport layer to the luminescent layer, and the increase in the driving voltage of the light-emitting element can be suppressed with reliability.

Preferably, the n-type electron transport layer contains 0.3% to 2.0% by weight of the electron donor material.

By setting the content of the electron donor material or electron injection material in this range, the diffusion of the electron injection material to the luminescent layer can be relatively small.

According to another aspect of the invention, a light-emitting device is provided which includes the above-described light-emitting element.

In the light-emitting device, the driving voltage can be maintained low even though it is operated at a constant current for a long time.

According to still another aspect of the invention, a display device is provided which includes the above-described light-emitting device.

The display device can be stably operated with reliability.

According to further aspect of the invention, an electronic apparatus is provided which includes the above-described display device.

The electronic apparatus is highly reliable.

### BRIEF DESCRIPTION OF THE DRAWINGS

The invention will be described with reference to the accompanying drawings, wherein like numbers reference like elements.

FIG. 1 is a schematic vertical sectional view of a light-emitting element according to an embodiment of the invention.

FIG. 2 is a vertical sectional view of a display device of an embodiment of the invention.

FIG. 3 is a perspective view of a mobile or notebook personal computer to which an embodiment of the electronic apparatus of the invention has been applied.

FIG. 4 is a perspective view of a mobile phone to which an embodiment of the electronic apparatus of the invention has been applied.

FIG. 5 is a perspective view of a digital still camera to which an embodiment of the electronic apparatus of the invention has been applied.

FIG. 6 is a representation showing profiles of lithium ions in light-emitting elements of Examples 1 and 2, analyzed by secondary ion mass spectrometry.

### DESCRIPTION OF EXEMPLARY EMBODIMENTS

Preferred embodiments of the light-emitting element, the light-emitting device, the display device, and the electronic apparatus of the invention will now be described with reference to the attached drawings.

### Light-Emitting Element

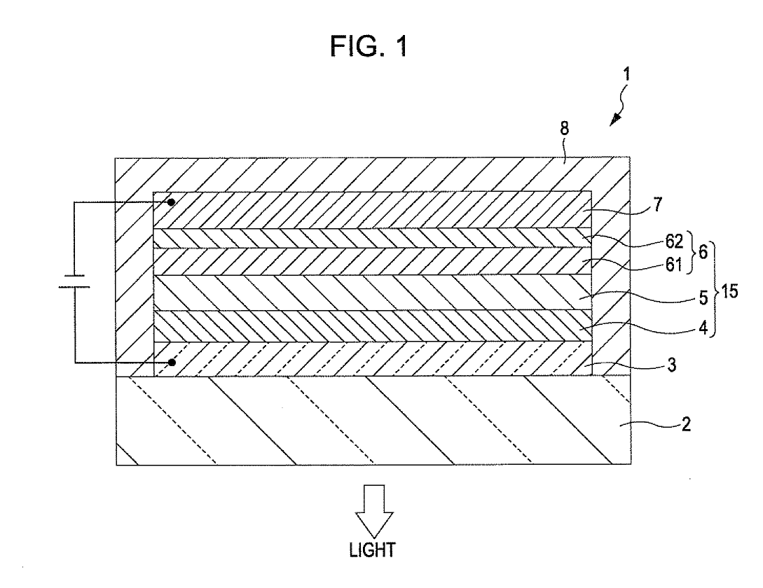

FIG. 1 is a schematic vertical sectional view of a light-emitting element according to an embodiment of the invention. For convenience sake, in the following description, the upper side of FIG. 1 is described as the upper side of the structure of the light-emitting element, and similarly the lower side of the figure is described as the lower side of the structure.

The light-emitting element (electroluminescent element) 1 includes an anode 3, a hole transport layer 4, a luminescent layer 5, an electron transport layer 6, and a cathode 7. These layers are formed in that order. In other words, the light-emitting element 1 has a multilayer composite 15 including, in this order from below, the hole transport layer 4, the luminescent layer 5 and the electron transport layer 6 between the two electrodes (anode 3 and cathode 7).

The entirety of the light-emitting element 1 is disposed on a substrate 2 and sealed with a sealing member 8. In the light-emitting element 1, by applying a driving voltage to the anode 3 and the cathode 7, holes are supplied (injected) to the luminescent layer 5 from the anode 3, and electrons are supplied (injected) to the luminescent layer 5 from the cathode 7. The holes and the electrons are recombined in the luminescent layer 5. The energy generated by the recombination forms excitons. When the excitons return to the ground state, energy is emitted as light (fluorescence or phosphorescence).

The substrate 2 supports the anode 3. The light-emitting element 1 of the present embodiment is of bottom emission type, in which light is emitted through the substrate 2. Accordingly, the substrate 2 and the anode 3 are substantially transparent (clear and colorless, clear and colored, or translucent).

For example, the substrate 2 may be made of a resin, such as polyethylene terephthalate, polyethylene naphthalate, polypropylene, cycloolefin polymer, polyamide, polyethersulfone, poly(methyl methacrylate), polycarbonate, or polyacrylate, or a glass material, such as quartz glass or soda glass. These materials may be used singly or in combination.

The substrate 2 preferably has an average thickness of, but not limited to, 0.1 to 30 mm, more preferably 0.1 to 10 mm.

If the light-emitting element 1 is of top emission type, in which light is emitted from the opposite side to the substrate 2, the material of the substrate 2 may be transparent or opaque. Such an opaque substrate may be made of a ceramic such as alumina, a metal coated with an oxide film (insulating film) such as stainless steel, or a resin.

The light-emitting element 1 is disposed on the substrate 2. Components constituting the light-emitting element 1 will be described below.

### Anode 3

The anode 3 is an electrode that injects holes to the hole transport layer 4. Preferably, the anode 3 is made of a material having a high work function and a high conductivity. The anode 3 may be made of oxides such as indium tin oxide (ITO), indium zinc oxide (IZO), In₃O₃, SnO₂, Sb-containing SnO₂, and Al-containing ZnO, metals such as Au, Pt, Ag, and Cu, and alloys containing these metals. These materials may be used singly or in combination. The anode 3 preferably has an average thickness of, but not limited t, 10 to 200 nm, more preferably 50 to 150 nm.

### Hole Transport Layer 4

The hole transport layer 4 transports holes injected from the anode 3 to the luminescent layer 5. The hole transport layer 4 may be made of a p-type polymer material, a p-type low-molecular-weight material, or a combination of these materials. Examples of such a material include tetraarylbenzidine derivatives, such as N,N′-di(1-naphthyl)-N,N′-diphenyl-1,1′-diphenyl-4,4′-diamine (NPD) and N,N′-diphenyl-N,N′-bis(3-methylphenyl)-1,1′-diphenyl-4,4′-diamine (TPD), and tetraaryldiaminofluorene compounds and their derivatives (amine-based compounds). These materials may be used singly or in combination.

Among these, hole transport materials having a benzidine structure are preferred. More preferably, it is a tetraarylbenzidine or its derivative. Thus, holes can be efficiently injected from the anode to the hole transport layer 4, and, in addition, can be efficiently transported to the luminescent layer 5. The hole transport layer 4 preferably has an average thickness of, but not limited to, 10 to 150 nm, more preferably 10 to 100 nm.

### Luminescent Layer 5

The luminescent layer 5 contains a luminescent material. Electrons supplied (injected) from the cathode 7 and holes supplied (injected) from the anode 3 are recombined to release energy, and the energy forms excitons. The luminescent material releases energy, that is, emits light (fluorescence or phosphorescence) when the excitons return to the ground state.

Any luminescent material can be used without particular limitation, and an appropriate material is selected according to the color to be emitted from the luminescent layer 5. Fluorescent materials and phosphorescent materials may be used singly or in combination. For example, for a luminescent layer 5 that emits white light, a material that can emit red light, a material that can emit green light and a material that can emit blue light may be used in combination.

More specifically, exemplary red fluorescent materials include, but are not limited to, perylene derivatives such as tetraaryldiindenoperylene derivatives, europium complexes, benzopyran derivatives, rhodamine derivatives, benzothioxanthene derivatives, porphyrin derivatives, nile red, 2-(1,1-dimethylethyl)-6-(2-(2,3,6,7-tetrahydro-1,1,7,7-tetramethyl-1H,5H-benzo(ij)quinolizine-9-yl)ethenyl)-4H-pyran-4H-ylidene)propanedinitrile (DCJTB), and 4-(dicyanomethylene)-2-methyl-6-(p-dimethylaminostyryl)-4H-pyran (DCM).

Exemplary blue fluorescent materials include, but are not limited to, distyryldiamine derivatives, distyryl derivatives, fluoranthene derivatives, pyrene derivatives, perylene and perylene derivatives, anthracene derivatives, benzoxazole derivatives, benzothiazole derivatives, benzoimidazole derivatives, chrysene derivatives, phenanthrene derivatives, distyrylbenzene derivatives, tetraphenylbutadiene, 4,4′-bis(9-ethyl-3-carbazovinylene)-1,1′-biphenyl (BCzVBi), poly[(9,9-dioctylfluorene-2,7-diyl)-co-(2,5-dimethoxybenzene-1,4-diyl)], poly[(9,9-dihexyloxyfluorene-2,7-diyl)-ortho-co-(2-methoxy-5-{2-ethoxyhexyloxy}phenylene-1,4-diyl)], poly[(9,9-dioctylfluorene-2,7-diyl)-co-(ethylenylbenzene)], 4,4′-bis[4-(diphenylamino)styryl]biphenyl (BDAVBi), and BD102 (product name, produced by Idemitsu Kosan). These materials may be used singly or in combination.

Exemplary green fluorescent materials include, but are not limited to, coumarin derivatives, quinacridone derivatives, 9,10-bis[(9-ethyl-3-carbazole)-vinylenyl]-anthracene, poly(9,9-dihexyl-2,7-vinylenefluorenylene), poly[(9,9-dioctylfluorene-2,7-diyl)-co-(1,4-diphenylene-vinylene-2-methoxy-5-{(2-ethylhexyloxy}benzene)], and poly[(9,9-dioctyl-2,7-divinylenefluorenylene)-ortho-co-(2-methoxy-5-(2-ethoxylhexyloxy)-1,4-phenylene)].

Exemplary yellow fluorescent materials include compounds having a naphthacene skeleton, formed by substituting naphthacene with a desired number (preferably 2 to 6) of aryl groups (preferably, phenyl groups), such as rubrene-based materials, and mono-indenoperylene derivatives.

Exemplary red phosphorescent materials include metal complexes, such as those of iridium, ruthenium, platinum, osmium, rhenium and palladium. At least one of the ligands of the metal complex may have a phenylpyridine skeleton, a bipyridyl skeleton, a porphyrin skeleton or the like. More specifically, examples of such a red phosphorescent material include tris(1-phenylisoquinoline) iridium (Ir(piq)₃), bis[2-(2′-benzo[4,5-α]thienyl)pyridinato-N,C³′]iridium (acetylacetonate) (btp2Ir(acac)) expressed by the following formula (1), 2,3,7,8,12,13,17,18-octaethyl-12H,23H-porphyrin-platinum (II), bis[2-(2′-benzo[4,5-α]thienyl)pyridinato-N,C³′]iridium, and bis(2-phenylpyridine)iridium(acetylacetonate).

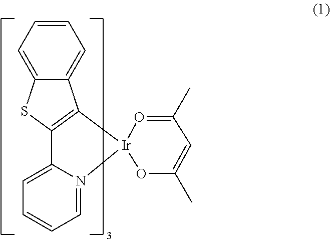

Exemplary blue phosphorescent materials include metal complexes, such as those of iridium, ruthenium, platinum, osmium, rhenium and palladium. More specifically, examples of such a blue phosphorescent material include bis[4,6-difluorophenylpyridinato-N,C²′]-picolinate-iridium, tris[2-(2,4-difluorophenyl)pyridinato-N,C²′]iridium, bis[2-(3,5-trifluoromethyl)pyridinato-N,C²′]-picolinate-iridium, and bis(4,6-difluorophenylpyridinato-N,C²′)iridium(acetylacetonate).

Exemplary green phosphorescent materials include metal complexes, such as those of iridium, ruthenium, platinum, osmium, rhenium and palladium. Among these, preferred are metal complexes at least one ligand of which has a phenylpyridine skeleton, a bipyridyl skeleton, a porphyrin skeleton or the like. More specifically, examples of such a metal complex include fac-tris(2-phenylpyridine) iridium (Ir(ppy)₃) expressed by the following formula (2), bis(2-phenylpyridinato-N,C²′)iridium(acetylacetonate), and fac-tris[5-fluoro-2-(5-trifluoromethyl-2-pyridine)phenyl-C,N]iridium.

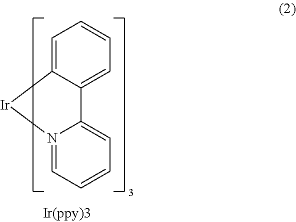

The luminescent layer 5 may further contain a host material so that the luminescent material acts as a guest material. In the luminescent layer 5, the host material may be doped with the guest material or luminescent material as a dopant. The host material helps the recombination of holes and electrons to form excitons, and transfers the energy of the excitons to the luminescent material (Ferster transfer or Dexter transfer) to excite the luminescent material.

Any host material can be used without particular limitation. If the luminescent material is fluorescent, examples of the host material include rubrene and rubrene derivatives, distyrylarylene derivatives, naphthacene-based materials such as bis(p-biphenylnaphthacene), anthracene derivatives such as 3-tert-butyl-9,10-di(naphth-2-yl)anthracene (TBADN), perylene derivatives such as bis(o-biphenylylperylene), pyrene derivatives such as tetraphenylpyrene, distyrylbenzene derivatives, stilbene derivatives, distyrylamine derivatives, quinolinolate-based metal complexes such as bis(2-methyl-8-quinolinolato)(p-phenylphenolato)aluminum (BAlq) and tris(8-quinolinolato) aluminum complexes (Alq₃), triarylamine derivatives such as triphenylamine tetramers, arylamine derivatives, oxadiazole derivatives, silole derivatives, carbazole derivatives, oligothiophene derivatives, benzopyran derivatives, triazole derivatives, benzoxazole derivatives, benzothiazole derivatives, quinoline derivatives, coronene derivatives, amine compounds, 4,4′-bis(2,2′-diphenylvinyl)biphenyl (DPVBi), and IDE 120 (product name, produced by Idemitsu Kosan). These materials may be used singly or in combination. If a blue or green luminescent material is used, preferred host materials include IDE 120 (produced Idemitsu Kosan), anthracene-based materials, and dianthracene-based materials. If a red luminescent material is used, preferred host materials include rubrene and rubrene derivatives, naphthacene-based materials, and perylene derivatives.

If the luminescent material contains a phosphorescent material, examples of the host material include carbazole derivatives such as 3-phenyl-4-(1′-naphthyl)-5-phenylcarbazole and 4,4′-N,N′-dicarbazolebiphenyl (CBP) expressed by the following formula (3), phenanthroline derivatives, triazole derivatives, quinolinolate-based metal complexes such as tris(8-quinolinolato)aluminum (Alq) and bis(2-methyl-8-quinolinolato)-4-(phenylphenolate)aluminum, carbazolyl-containing organic compounds such as N-dicarbazolyl-3,5-benzene, poly(9-vinylcarbazole), 4,4′,4″-tris(9-carbazolyl)triphenylamine and 4,4′-bis(9-carbazolyl)-2,2′-dimethylbiphenyl, and 2,9-dimethyl-4,7-diphenyl-1,10-phenanthroline (BCP). These compounds may be used singly or in combination.

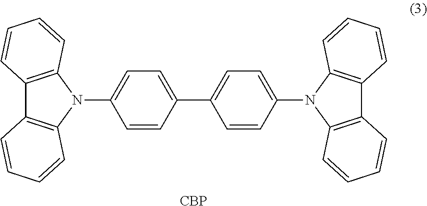

If these luminescent materials (guest materials) and host materials are used, the luminescent material content (amount of dopant) in the luminescent layer 5 is preferably 0.1% to 30% by weight, and more preferably 0.5% to 20% by weight. By controlling the luminescent material content in these ranges, the luminous efficiency can be optimized.

Preferably, the luminescent layer 5 has an average thickness in the range of 30 to 100 nm, more preferably in the range of 30 to 70 nm, and still more preferably in the range of 30 to 50 nm. Thus, the emission characteristics of the luminescent layer 5 can be maintained relatively good even if the constituents of the n-type electron transport layer 62 (particularly, the electron injection material) diffuses into the luminescent layer 5. In addition, by controlling the thickness of the luminescent layer 5 in an appropriate range, the initial driving voltage of the light-emitting element 1 can prevented from increasing. Hence, the driving voltage of the light-emitting element 1 can be set low.

Although the luminescent layer 5 in the present embodiment has a single-layer structure, the luminescent layer 5 may have a multilayer structure including a plurality of luminescent sub layers. In this instance, the color of light emitted from the sub layers may be the same or different. If the luminescent layer 5 includes a plurality of sub layers, the sub layers may be separated from one another by intermediate layers.

### Electron Transport Layer 6

The electron transport layer 6 transports electrons injected from the cathode 7 to the luminescent layer 5. The electron transport layer 6 includes the buffer layer 61 and the n-type electron transport layer 62 in that order in the direction from the anode 3 to the cathode 7. The present embodiment is featured by this structure of the electron transport layer 6. The layers of the electron transport layer 6 will be described in detail below.

n-Type Electron Transport Layer 62

The n-type electron transport layer 62 is disposed between the buffer layer 61 and the cathode 7, and functions to transport electrons injected from the cathode 7 to the luminescent layer 5.

The n-type electron transport layer 62, in the present embodiment, is formed of a mixture containing mainly an electron transport material that can transport electrons, and further an electron injection material (electron donor material) that can inject electrons.

By providing an n-type electron transport layer 62 having such a feature, that is, a structure containing an electron transport material and an electron injection material, the n-type electron transport layer 62 can exhibit particularly superior electron transporting ability and electron injection ability. Consequently, electrons can be efficiently injected from the cathode 7 to the n-type electron transport layer 62 and further to the anode 3 through the n-type electron transport layer 62 even if the light-emitting element 1 is operated at a low voltage. Accordingly, the heat from the light-emitting element 1 can be reduced a relatively low temperature range.

Also, since the electron transport material in the n-type electron transport layer 62 is doped with an electron injection material, the electron transport material receives electrons from the electron injection material to come into a radical state. Consequently, the light-emitting element 1 can be operated at a low voltage.

Examples of the electron transport material used in the n-type electron transport layer 62 include organic metal complexes including 8-quinolinol or its derivatives (quinoline derivatives) as a ligand, such as tris(8-quinolinolato) aluminum (Alq₃), and oxadiazole derivatives such as 1,3-bis(N,N-t-butyl-phenyl)-1,3,4-oxadiazole (OXD-7) and 2-[1,1′-biphenyl]-4-yl-5-[4-(1,1-dimethylethyl)phenyl]-1,3,4-oxadiazole (PBD), perylene derivatives, pyridine derivatives, pyrimidine derivatives, quinoxaline derivatives, diphenylquinone derivatives, nitro-substituted fluorene derivatives, and other organic compounds not containing a metal element. These materials may be used singly or in combination.

The electron injection material (electron donor material) used in the n-type electron transport layer 62 may be an inorganic insulating material or an inorganic semiconductor material. Exemplary inorganic insulating materials include alkali metal chalcogenides (oxides, sulfides, selenides, and tellurides), alkaline-earth metal chalcogenides, alkali metal halides and alkaline-earth metal halides. These materials may be used singly or in combination. Since these inorganic insulating materials have high electron injection ability, electrons supplied from the cathode 7 can be efficiently injected to the luminescent layer 5. Consequently, electrons can be injected at a low voltage. Accordingly, the heat from the light-emitting element 1 can be reduced in a relatively low temperature range even if the light-emitting element 1 is continuously operated at a constant current.

Exemplary alkali metal chalcogenides include Li₂O, LiO, Na₂S, Na₂Se, and NaO. Exemplary alkaline-earth metal chalcogenides includes CaO, BaO, SrO, BeO, BaS, MgO, and CaSe. Exemplary alkali metal halides include CsF, LiF, NaF, KF, LiCl, KCl, and NaCl. Exemplary alkaline-earth metal halides include CaF₂, BaF₂, SrF₂, MgF₂, and BeF₂.

Examples of the inorganic semiconductor material used as the electron injection material include oxides, nitrides and oxynitrides containing at least one element selected from the groups consisting of Li, Na, Ba, Ca, Sr, Yb, Al, Ga, In, Cd, Mg, Si, Ta, Sb and Zn. These materials may be used singly or in combination.

Preferably, the electron injection material (electron donor material) used in the n-type electron transport layer 62 is an alkali metal compound or an alkaline-earth metal compound, or their combination, and Li₂O is particularly preferred. Thus, the electron injection ability of the n-type electron transport layer 62 can be enhanced while the electron transporting ability of the n-type electron transport layer 62 can be good. Alkali metal compounds (such as alkali metal chalcogenides and alkali metal halides) have very low work functions. By using such an alkali metal compound in the n-type electron transport layer 62, the light-emitting element 1 can emit light with a high luminance. In particular, the use of Li₂O facilitates electron injection at a low voltage. Accordingly, the heat from the light-emitting element 1 can be reduced in a relatively low temperature range even if the light-emitting element 1 is continuously operated at a constant current.

In addition, the n-type electron transport layer 62 functions to block holes. The n-type electron transport layer 62, containing an electron transport material and an electron injection material, can be formed by codeposition or the like of the electron transport material and the electron injection material in which the electron transport material is doped as a host material with the electron injection material acting as a guest material.

Preferably, the electron injection material content (amount of dopant) in the n-type electron transport layer 62 is in the range of 0.3% to 2.0% by weight, and more preferably in the range of 0.5% to 1.5% by weight. By controlling the electron injection material content in these ranges, the n-type electron transport layer 62 can exhibit high electron transporting ability and electron injection ability with a good balance. Also, the diffusion of the electron injection material into the luminescent layer 5 can be reduced.

The concentration of the electron injection material in the n-type electron transport layer 62 may be gradually increased in the direction toward the anode 3 from the cathode 7 so that electrons supplied from the cathode 7 can be efficiently transported and injected to the luminescent layer 5, and so that the diffusion of the electron injection material from the n-type electron transport layer 62 to the luminescent layer 5 can be reduced to increase the lifetime of the light-emitting element 1. In this instance, the concentration of the electron injection material may be varied in steps or continuously.

The n-type electron transport layer 62 preferably has an average thickness of, but not limited to, 10 to 100 nm, more preferably 10 to 50 nm. Thus, the electrons injected from the cathode 7 can be efficiently transported to the anode 3, and holes having passed through the luminescent layer 5 can be blocked.

### Buffer Layer 61

The buffer layer 61 is disposed between the luminescent layer 5 and the n-type electron transport layer 62, that is, disposed to the luminescent layer 5 side of the n-type electron transport layer 62. The buffer layer can transport electrons and functions to prevent the electron injection material from diffusing into the luminescent layer 5 from the n-type electron transport layer 62.

The buffer layer 61 thus reliably prevents degradation of emission characteristics of the luminescent layer 5, which is caused by the mechanism in which excitons formed by recombination of electrons and holes in the luminescent layer 5 are deactivated by diffusion of the electron injection material into the luminescent layer 5. Consequently, the light-emitting element 1 can exhibit a satisfactory luminance for a long time.

In the present embodiment, the buffer layer 61 mainly contains an electron transport material that can transport electrons. By adding an electron transport material to the buffer layer 61, the buffer layer 61 can function as above. The same electron transport material used as the first electron transport material in the n-type electron transport layer 62 can be used as the second electron transport material in the buffer layer 61.

The first electron transport material and the second electron transport material may be the same or different. Preferably, different types are selected so that the electron injection material can be more diffusible in the n-type electron transport layer 62 than in the buffer layer 61. Since the electron injection material is less diffusible in the buffer layer 61 than in the n-type electron transport layer 62, the electron injection material can be confined in the n-type electron transport layer 62 more effectively.

As for the diffusivity of the electron injection material in the n-type electron transport layer 62 and the buffer layer 61, when an electron injection material in a layer with a certain concentration gradient moves at a higher velocity than in another layer, the electron injection material is more diffusible in the former layer, and less diffusible in the latter layer.

Preferably, the first electron transport material and the second electron transport material are selected so that the electron mobility of the first electron transport material can be higher than that of the second electron transport material. The presence of the buffer layer 61 between the luminescent layer 5 and the n-type electron transport layer 62 can increase the driving voltage of the light-emitting element 1. However, by selecting the first electron transport material and the second electron transport material so as to satisfy the above-described relationship in electron mobility, that is, by selecting a material having a higher electron mobility as the material of the n-type electron transport layer 62, the driving voltage of the light-emitting element 1 can be maintained relatively low.

For a preferred combination of the first electron transport material and the second electron transport material, accordingly, an organic material not containing a metal is selected as the first electron transport material and an organic metal complex is selected as the second electron transport material, from the electron transport materials cited in the description of the n-type electron transport layer 62. Thus, both the diffusion of the electron injection material to the luminescent layer 5 and the increase in the driving voltage of the light-emitting element 1 can be appropriately reduced or prevented.

The buffer layer 61 preferably has an average thickness of, but not limited to, 3 to 20 nm, more preferably 5 to 15 nm. Thus, the electron injection material can be reliably prevented from diffusing from the n-type electron transport layer 62 to the luminescent layer 5, and the increase in the driving voltage of the light-emitting element can be reliably suppressed.

### Cathode 7

The cathode 7 is an electrode that injects electrons to the electron transport layer 6. Preferably, the cathode 7 is made of a material having a low work function. Examples of the material of the cathode 7 include Li, Mg, Ca, Sr, La, Ce, Er, Eu, Sc, Y, Yb, Ag, Cu, Al, Cs, Rb, and alloys containing these metals. These materials may be used singly, or in combination (for example, in a form of a multilayer composite).

If the cathode 7 is made of an alloy, it is preferable that an alloy containing a stable metallic element, such as Ag, Al or Cu, be used. More specifically, alloys such as MgAg, AlLi and CuLi are preferred. These alloys can enhance the electron injection efficiency and stability of the cathode 7.

The cathode 7 preferably has an average thickness of, but not limited to, 100 to 400 nm, more preferably 100 to 200 nm.

Since the light-emitting element 1 of the present embodiment is of bottom emission type, the cathode 7 does not need to be optically transparent.

### Electron Injection Layer

An electron injection layer may be provided between the electron transport layer 6 and the cathode 7. By forming a structure including an electron injection layer, the efficiency of electron injection from the cathode 7 to the electron transport layer 6 can be increased. The electron injection layer is made of an electron injection material such as inorganic insulating material or an inorganic semiconductor material.

Exemplary inorganic insulating materials include alkali metal chalcogenides (oxides, sulfides, selenides, and tellurides), alkaline-earth metal chalcogenides, alkali metal halides and alkaline-earth metal halides. These materials may be used singly or in combination. The electron injection layer mainly containing such a material can exhibit higher electron injection ability. In particular, alkali metal compounds (such as alkali metal chalcogenides and alkali metal halides) have very low work functions. By using such a material in the electron injection layer, the light-emitting element 1 can emit light with a high luminance.

Exemplary alkali metal chalcogenides include Li₂O, LiO, Na₂S, Na₂Se, and NaO. Exemplary alkaline-earth metal chalcogenides includes CaO, BaO, SrO, BeO, BaS, MgO, and CaSe. Exemplary alkali metal halides include CsF, LiF, NaF, KF, LiCl, KCl, and NaCl. Exemplary alkaline-earth metal halides include CaF₂, BaF₂, SrF₂, MgF₂, and BeF₂.

Examples of the inorganic semiconductor material used as the electron injection material include oxides, nitrides and oxynitrides containing at least one element selected from the groups consisting of Li, Na, Ba, Ca, Sr, Yb, Al, Ga, In, Cd, Mg, Si, Ta, Sb and Zn. These materials may be used singly or in combination.

The electron injection layer preferably has an average thickness of, but not limited to, 0.1 to 1000 nm, more preferably 0.2 to 100 nm, and still more preferably 0.2 to 50 nm.

### Sealing Member 8

The sealing member 8 covers the anode 3, the hole transport layer 4, the luminescent layer 5, the electron transport layer 6, and the cathode 7 to seal them for air tightness, and blocks oxygen and moisture. The presence of the sealing member 8 enhances the reliability of the light-emitting element 1 and prevents the deterioration or alteration of the light-emitting element 1 to enhance the durability.

The sealing member 8 may be made of a metal such as Al, Au, Cr, Nb, Ta, Ti or an alloy containing these elements, silicon oxide, or a resin material. If the sealing member 8 is electrically conductive, it is preferable that an insulating film be optionally provided between the sealing member 8 and each of the anode 3, the hole transport layer 4, the luminescent layer 5, the electron transport layer 6 and the cathode 7 to prevent short-circuiting. The sealing member 8 may be flat and oppose the substrate 2 with a sealant of, for example, a thermosetting resin filling the space therebetween.

In the light-emitting element 1 having the above-described structure, by applying a voltage between the anode 3 and the cathode 7, holes are supplied (injected) to the luminescent layer 5 from the anode 3, and electrons are supplied (injected) to the luminescent layer 5 from the cathode 7. The electrons and the holes are thus transported to the luminescent layer 5 and recombined in the luminescent layer 5, so that the luminescent layer 5 emits light.

In particular, the light-emitting element 1 has the buffer layer 61 that functions to prevent the electron injection material in the n-type electron transport layer 62 from diffusing into the luminescent layer 5. Consequently, the decrease in luminance lifetime, which results from the degradation of the emission characteristics of the luminescent layer 5, can be appropriately suppressed or prevented.

### Method for Manufacturing the Light-Emitting Element

The light-emitting element 1 may be manufactured in the following process.

(1) First, a substrate 2 is prepared, and an anode 3 is formed on the substrate 2. The anode 3 can be formed by chemical vapor deposition (CVD) such as plasma CVD or thermal CVD, dry plating such as vacuum vapor deposition, wet plating such as electroplating, thermal spraying, sol-gel method, metal organic deposition (MOD), or metal foil bonding.

(2) Subsequently, a hole transport layer 4, a luminescent layer 5, and an electron transport layer 6 (a buffer layer 61 and an n-type electron transport layer 62) are formed in that order on the anode 3. These layers can be formed by a gas phase process using, for example, CVD or dry plating such as vacuum vapor deposition or sputtering. Alternatively, the layers may be formed by applying a liquid material onto the anode 3 (or the layers overlying the anode) and drying the material (removing the solvent or disperse medium). Each liquid material can be prepared by dissolving the material of the layer in a solvent or dispersing it in a disperse medium.

The liquid material may be applied by a coating method, such as spin coating, roll coating, or ink jet printing. Such a coating method facilitates the formation of the layers on the anode 3 one after another. The solvent or disperse medium for each liquid material may be an inorganic solvent, an organic solvent or their mixture.

For drying, the coating of the liquid material may be allowed to stand under atmospheric pressure or reduced pressure, or may be heated. An inert gas may be blown to the coating.

Before forming the layers, the upper surface of the anode 3 may be subjected to oxygen plasma treatment. This surface treatment may impart lyophilicity to the upper surface of the anode 3, remove organic deposit on the upper surface of the anode 3, and adjust the work function around the upper surface of the anode 3. Preferably, the oxygen plasma treatment is performed, for example, at a plasma power of about 100 to 800 W and an oxygen gas flow rate of about 50 to 100 mL/min while the anode 3 (member to be treated) is transported at a speed of about 0.5 to 10 mm/s with the substrate 2 heated to about 70 to 90° C.

(3) Subsequently, a cathode 7 is formed on the electron transport layer 6. The cathode 7 can be formed by, for example, vacuum vapor deposition, sputtering, metal foil bonding, or applying an ink containing metal particles and firing the ink.

Thus, the light-emitting element 1 is produced through the above steps.

Finally, the light-emitting element 1 is covered with a sealing member 8, and the sealing member 8 is bonded to the substrate 2.

The resulting light-emitting element 1 may be used as a light source. The light-emitting elements 1 may be arranged in a matrix manner for a display device.

The display device may be operated by any technique without particular limitation. For example, the display device may be of active matrix type or passive matrix type.

### Display Device

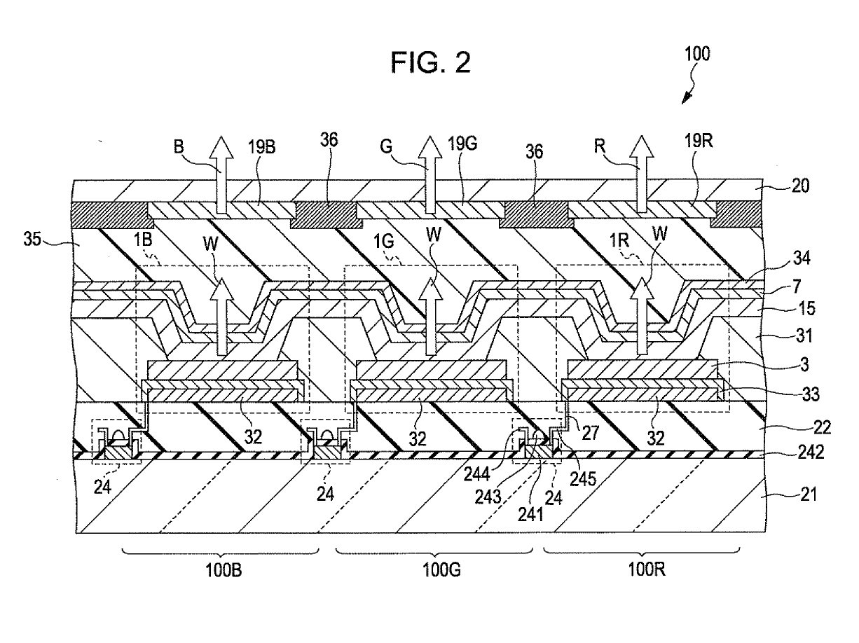

A display device of an embodiment of the invention will now be described. FIG. 2 is a vertical sectional view of a display device of an embodiment of the invention. The display device 100 shown in FIG. 2 includes a substrate 21, light-emitting elements 1R, 1G and 1B and color filters 19R, 19G and 19B that are provided corresponding to sub pixels 100R, 100G and 100B respectively, and driving transistors 24 that drive the corresponding light-emitting elements 1R, 1G and 1B. In the present embodiment, the display device 100 is a top emission display panel.

The driving transistors 24 are formed on the substrate 21, and a planarizing layer 22 made of an insulting material covers the driving transistors 24. Each driving transistor 24 includes a silicon semiconductor layer 241, a gate insulating layer 242 on the semiconductor layer 241, and a gate electrode 243, a source electrode 244 and a drain electrode 245 that are formed on the gate insulating layer 242.

Light-emitting elements 1R, 1G and 1B are disposed on the planarizing layer 22 so as to correspond to the driving transistors 24. The light-emitting element 1R includes a reflection film 32, an anti-corrosion film 33, an anode 3, a multilayer composite (organic EL emission portion) 15, a cathode 7, and a cathode cover 34 in that order from blow on the planarizing layer 22. The anode 3 of each of the light-emitting elements 1R, 1G and 1B acts as a pixel electrode and is electrically connected to the drain electrode 245 of the corresponding driving transistor 24 with a conductor portion (wire) 27. The cathode 7 of each of the light-emitting elements 1R, 1G and 1B is their common electrode.

The structure of the other light-emitting elements 1G and 1B is the same as that of the light-emitting element 1R. In FIG. 2, the same parts as in FIG. 1 are designated by the same reference numerals. The structure and characteristics of the reflection film 32 may be different among the light-emitting elements 1R, 1G and 1B according to the wavelength of light.

The light-emitting elements 1R, 1G and 1B are separated from one another by a partition member 31. The light-emitting elements 1R, 1G and 1B are covered with an epoxy resin layer 35.

The color filters 19R, 19G and 19B are disposed on the epoxy resin layer 35 corresponding to the light-emitting elements 1R, 1G and 1B. The color filter 19R changes the white light W from the light-emitting element 1R into red light. The color filter 19G changes the white light W from the light-emitting element 1G into green light. The color filter 19B changes the white light W from the light-emitting element 1B into blue light. By using these color filters 19R, 19G and 19B in combination with the light-emitting elements 1R, 1G and 1B, the display device 100 can display full color images.

The color filters 19R, 19G and 19B are separated from each other by a light-shielding layer 36. Emission from unintended ones of the sub pixels 100R, 100G and 100B thus can be prevented. The color filters 19R, 19G and 19B and the light-shielding layer 36 are covered with a sealing substrate 20.

The display device 100 may display monochrome images, or may display color images by using appropriate luminescent materials in the light-emitting elements 1R, 1G and 1B. The display device 100 according to an embodiment of the invention can be incorporated in various types of electronic apparatuses.

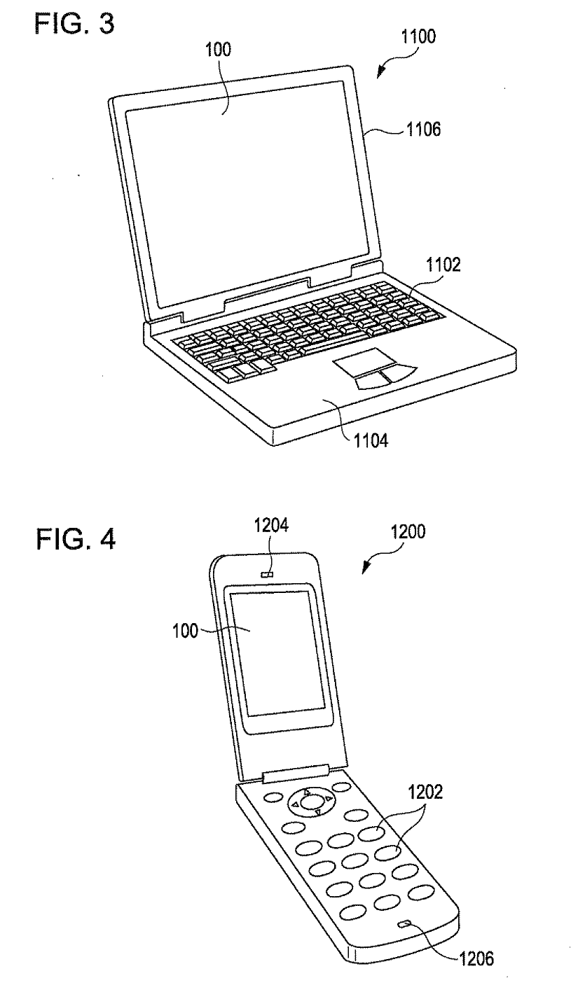

FIG. 3 is a perspective view of a mobile or notebook personal computer to which an embodiment of the electronic apparatus of the invention has been applied. In FIG. 3, the personal computer 1100 includes a body 1104 with a key board 1102, and a display unit 1106 having a display portion. The display unit 1106 is rotatably secured to the body 1104 with a hinge structure. The display portion of the display unit 1106 includes the display device 100 described above.

FIG. 4 is a perspective view of a mobile phone to which an embodiment of the electronic apparatus of the invention has been applied. In FIG. 4, the mobile phone 1200 includes a plurality of control buttons 1202, a receiver 1204, a microphone 1206, and a display portion. The display portion includes the above-described display device 100.

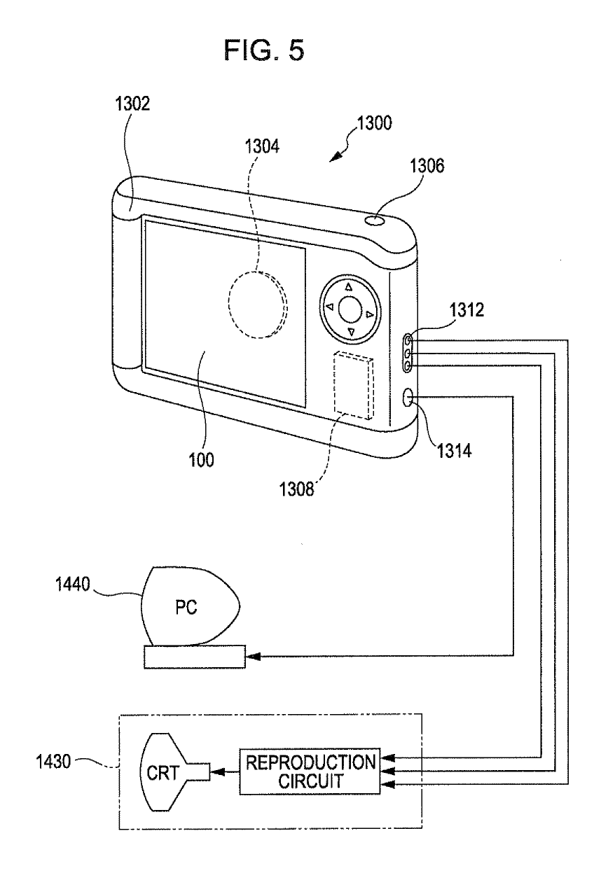

FIG. 5 is a perspective view of a digital still camera to which an embodiment of the electronic apparatus of the invention has been applied. FIG. 5 schematically shows the connection between the electronic apparatus and external devices. While conventional cameras expose a silver halide photographic film with an optical image of an object, the digital still camera 1300 converts an optical image of an object into electrical signals with a CCD (Charge Coupled Device) to produce image pickup signals (image signals).

The digital still camera 1300 includes a case or body 1302 and a display portion on the rear side of the body 1302. The display portion is configured to display images according to image pickup signals of the CCD, and functions as a finder to display an object as an electronic image. In the digital still camera 1300, the display portion includes the above-described display device 100.

A circuit board 1308 is disposed within the case 1302. The circuit board 1308 includes a memory device in which image pickup signals are stored. A light-receiving unit 1304 including an optical lens (image pickup optical system) and a CCD is disposed on the front side of the case 1302 (rear side of the figure). The user makes sure that an object to be taken is appropriately displayed on the display portion, and presses the shutter button 1306. Then the image pickup signals at that time of the CCD are transmitted to be stored to the memory device on the circuit board 1308.

The digital still camera 1300 is provided with a video signal output terminal 1312 and a data communication Input terminal 1314 on a side of the case 1302. The video signal output terminal 1312 is connected to a television monitor 1430, and the data communication input terminal 1314 is connected to a personal computer 1440. The image pickup signals stored in the memory device of the circuit board 1308 are output to the television monitor 1430 or the personal computer 1440 by a predetermined operation.

The electronic apparatuses according to embodiments of the invention can be applied to television sets, video cameras, viewfinder-type or monitor-direct-view-type video tape recorders, car navigation systems, pagers, electronic notebooks (may have a communication function), electronic dictionaries, electronic calculators, electronic game machines, word processors, work stations, video phones, security video monitors, electronic binoculars, PUS terminals, apparatuses with a touch panel such as cash dispensers and automatic ticket vending machines, medical instruments such as electronic thermometers, blood-pressure meters, blood glucose meters, electrocardiographic monitors, ultrasonographs and endoscope monitors, fishfinders, and other measuring apparatuses or meters for vehicles, planes and ships, flight simulators, other monitors, and projection monitors such as projectors, in addition to the personal computer (mobile personal computer) shown in FIG. 3, the mobile phone shown in FIG. 4, and the digital still camera shown in FIG. 5.

Although the light-emitting element, the light-emitting device, the display device, and the electronic apparatus have been described with reference to embodiments shown in the drawings, the invention is not limited to the disclosed embodiments.

For example, although the luminescent layer of the above-described light-emitting element has a single-layer structure, the luminescent layer may include two or more layers.

### EXAMPLES

Examples of the invention will now be described.

### 1. Preparation of Light-Emitting Elements

### Example 1

(1) First, a transparent glass substrate having an average thickness of 0.5 mm was prepared. Then, an ITO electrode (anode) was formed to an average thickness of 50 nm on the substrate by sputtering. After being subjected to ultrasonic cleaning in acetone and 2-propanol in that order, the resulting substrate was treated with oxygen plasma.

(2) Subsequently, N,N′-di(1-naphthyl)-N,N′-diphenyl-1,1′-diphenyl-4,4′-diamine (α-NPD) was deposited on the ITO electrode by vacuum vapor deposition, thus forming a hole transport layer having an average thickness of 80 nm.

(3) Then, a luminescent layer having an average thickness of 30 nm was formed on the hole transport layer by vacuum vapor deposition. In this operation, the luminescent layer was formed of a mixture of BDAVBi acting as a blue luminescent material (guest material) and TBADN acting as a host material. The blue luminescent material content (dopant concentration) in the luminescent layer was 10% by weight.

(4) Subsequently, tris(8-quinolinolato) aluminum (Alq₃) was deposited on the luminescent layer by vacuum vapor deposition, thus forming a buffer layer having an average thickness of 10 nm.

(5) Then, 1,3-bis(N,N-t-butyl-phenyl)-1,3,4-oxadiazole (OXD-7) acting as an electron transport material and Li₂O acting as an electron injection material were deposited on the buffer layer by vacuum vapor deposition, thus forming an n-type electron transport layer having an average thickness of 30 nm. In this instance, the weight ratio of OXD-7 to Li₂O was 99:1 in the n-type electron transport layer.

An electron transport layer including the buffer layer and the n-type electron transport layer was thus formed through the above steps (4) and (5).

(6) Subsequently, lithium fluoride (LiF) was deposited on the electron transport layer by vacuum vapor deposition, thus forming an electron injection layer having an average thickness of 1.0 nm.

(7) Then, aluminum (Al) was deposited on the electron injection layer by vacuum vapor deposition. Thus, an Al cathode having an average thickness of 100 nm was formed.

(8) The resulting layers were covered with a glass protective cover (sealing member) for sealing the layers, and the protective cover was fixed with an epoxy resin.

Through the above-described steps, a light-emitting element, which includes the anode, the hole transport layer, the luminescent layer, the electron transport layer (the buffer layer and the n-type electron transport layer) and the cathode in this order from bellow, was formed on the substrate.

### Example 2

A light-emitting element was prepared in the same manner as in Example 1 except that the buffer layer was formed by the following operation (4A) instead of the operation of step (4).

(4A) A buffer layer having an average thickness of 10 nm was formed on the luminescent layer by vacuum vapor deposition of OXD-7.

### Example 3

A light-emitting element was prepared in the same manner as in Example 1 except that the n-type electron transport layer was formed by the following operation (5B) instead of the above operation of step (5).

(5B) An n-type electron transport layer having an average thickness of 30 nm was formed on the buffer layer by vacuum vapor deposition of Alq₃ acting as an electron transport material and Li₂O acting as an electron injection material. In this instance, the weight ratio of Alq₃ to Li₂O was 99:1 in the n-type electron transport layer.

### Example 4

A light-emitting element was prepared in the same manner as in Example 1 except that the buffer layer and the n-type electron transport layer were formed by the following operations (4C) and (5C) instead of the above operations of steps (4) and (5).

(4C) A buffer layer having an average thickness of 10 nm was formed on the luminescent layer by vacuum vapor deposition of OXD-7.

(5C) An n-type electron transport layer having an average thickness of 30 nm was formed on the buffer layer by vacuum vapor deposition of Alq₃ acting as an electron transport material and Li₂O acting as an electron injection material. In this instance, the weight ratio of Alq₃ to Li₂O was 99:1 in the n-type electron transport layer.

### Example 5

A light-emitting element was prepared in the same manner as in Example 1 except that the buffer layer was formed by the following operation (4D) instead of the above operation of step (4).

(4D) A buffer layer having an average thickness of 10 nm was formed on the luminescent layer by vacuum vapor deposition of 2-[1,1′-biphenyl]-4-yl-5-[4-(1,1-dimethylethyl)phenyl]-1,3,4-oxadiazole (PBD).

### Example 6

A light-emitting element was prepared in the same manner as in Example 1 except that the n-type electron transport layer was formed by the following operation (5E) instead of the above operation of step (5).

(5E) An n-type electron transport layer having an average thickness of 30 nm was formed on the buffer layer by vacuum vapor deposition of PBD acting as an electron transport material and Li₂O acting as an electron injection material. In this instance, the weight ratio of PBD to Li₂O was 99:1 in the n-type electron transport layer.

### Comparative Example 1

A light-emitting element was prepared in the same manner as in Example 1 except that the operation of step (4) for forming the buffer layer was omitted.

### Comparative Example 2

A light-emitting element was prepared in the same manner as in Example 3 except that the operation of step (4) for forming the buffer layer was omitted.

### 2. Evaluation

A current was applied between the anode and the cathode of each light-emitting element of Examples and Comparative Examples from a direct power source at a current density of 10 mA/cm², and the driving voltage of the light light-emitting element was measured. Each measurement was normalized with the driving voltage measured in Example 1.

A current was further applied between the anode and the cathode of the light-emitting elements from the direct power source at a current density of 100 mA/cm², and the time (LT80) until the luminance was reduced to 80% of the initial luminance was measured. The measurements of LT80 were normalized with the LT80 measured in Example 1.

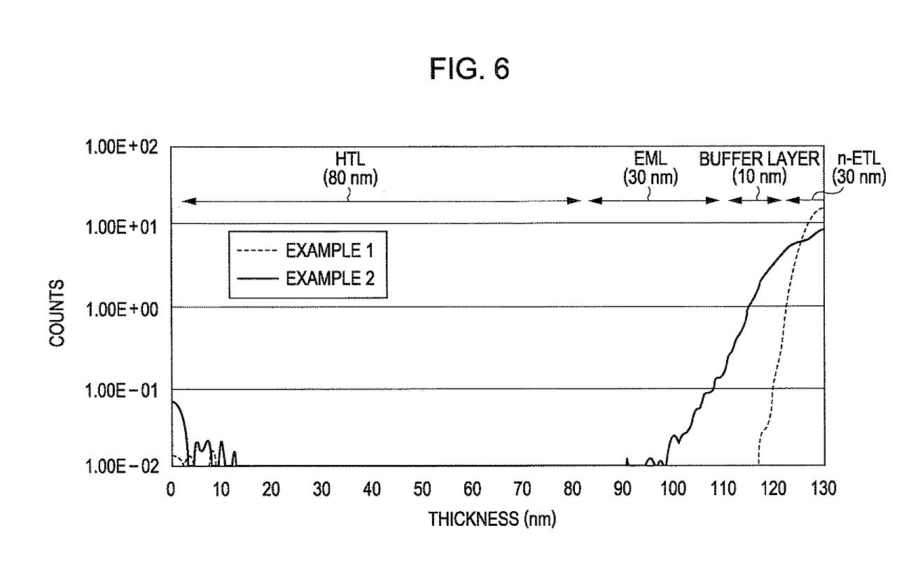

Light was emitted from the light-emitting elements of Examples 1 and 2 until the luminance was reduced to 80% of the initial luminance by applying a current at a current density of 100 mA/cm² between the anode and the cathode from the direct power source. Then, each light-emitting element was subjected to secondary ion mass spectrometry (SIMS) to measure the Li ion strength in the direction from the anode to the cathode. The results are shown in the Table and FIG. 6.

TABLE

| | | | n-Type electron | | | |
|---|---|---|---|---|---|---|
| | Buffer layer | | transport layer | | | |
| | Electron | | Electron | | LT80 | Relative |
| | transport | Thickness | transport | Thickness | (Luminance | driving |
| | material | [nm] | material | [nm] | lifetime) | voltage |
| Example 1 | Alq₃ | 10.0 | OXD-7 | 30.0 | 6.10 | 1.30 |
| Example 2 | OXD-7 | 10.0 | OXD-7 | 30.0 | 1.60 | 1.10 |
| Example 3 | Alq₃ | 10.0 | Alq₃ | 30.0 | 6.40 | 2.20 |
| Example 4 | OXD-7 | 10.0 | Alq₃ | 30.0 | 5.20 | 1.90 |
| Example 5 | PBD | 10.0 | OXD-7 | 30.0 | 1.50 | 1.20 |
| Example 6 | Alq₃ | 10.0 | PBD | 30.0 | 6.20 | 1.40 |
| Comparative | — | 0 | OXD-7 | 30.0 | 1.00 | 1.00 |
| Example 1 | | | | | | |
| Comparative | — | 0 | Alq₃ | 30.0 | 5.10 | 2.00 |
| Example 2 | | | | | | |

As is clear from the Table, the results of comparisons between the light-emitting elements of Examples 1, 2, 5 and 6 and the light-emitting element of Comparative Example 1, and between the light-emitting elements of Examples 3 and 4 and the light-emitting element of Comparative Example 2 show that the presence of the buffer layer allows the light-emitting element to be operated at a low driving voltage, prevents the electron injection material (Li₂O) from diffusing from the n-type electron transport layer to the luminescent layer, and thus contributes to the increase in the lifetime of the light-emitting element.

Also, as shown in FIG. 6, which shows the comparison between Example 1 in which the buffer layer contained an organic metal complex as an electron transport material and Example 2 in which the buffer layer contained a metal-free organic compound, it has been found that the diffusion of the electron injection material (Li₂O) in the buffer layer and the luminescent layer was suppressed in Example 1 and, consequently, the lifetime of the light-emitting element of Example 1 was increased. In FIG. 6, HTL represents the hole transport layer; EML represents the luminescent layer; and n-ETL represents the electron transport layer.

This application claims priority from Japanese Patent Application No. 2011-049643 filed in the Japanese patent office on Mar. 7, 2011, the entire disclosure of which is hereby incorporated by reference in its entirely.

What is claimed is:

1. A light-emitting element comprising:
an anode;
a cathode;
a luminescent layer between the anode and the cathode that emits light by applying a current between the anode and the cathode; and
an electron transport layer between the cathode and the luminescent layer that transports electrons from the cathode to the luminescent layer, and includes an n-type electron transport layer and a buffer layer in contact with the n-type electron transport layer,
wherein the n-type electron transport layer contains a first electron transport material and an electron injection material and is disposed to the cathode side of the buffer layer, and the buffer layer contains a second electron transport material and is disposed to the luminescent layer side of the n-type electron transport layer so as to prevent the electron injection material from diffusing from the n-type electron transport layer to the luminescent layer.

2. The light-emitting element according to claim 1, wherein the first electron transport material and the second electron transport material are such a combination as the electron injection material is less diffusible in the buffer layer than in the n-type electron transport layer.

3. The light-emitting element according to claim 1, wherein the first electron transport material has a higher electron mobility than the second electron transport material.

4. The light-emitting element according to claim 2, wherein the first electron transport material is an organic compound not containing a metal, and the second electron transport material is an organic metal complex.

5. The light-emitting element according to claim 1, wherein the electron injection material is at least one substance selected from the group consisting of alkali metals, alkaline-earth metals, alkali metal compounds, and alkaline-earth metal compounds.

6. The light-emitting element according to claim 1, wherein the buffer layer has an average thickness in the range of 3.0 to 20.0 nm.

7. The light-emitting element according to claim 1, wherein the n-type electron transport layer contains 0.3% to 2.0% by weight of the electron injection material.

8. A light-emitting device comprising the light-emitting element as set forth in claim 1.

9. A light-emitting device comprising the light-emitting element as set forth in claim 2.

10. A light-emitting device comprising the light-emitting element as set forth in claim 3.

11. A light-emitting device comprising the light-emitting element as set forth in claim 4.

12. A light-emitting device comprising the light-emitting element as set forth in claim 5.

13. A display device comprising the light-emitting device as set forth in claim 8.

14. A display device comprising the light-emitting device as set forth in claim 9.

15. A display device comprising the light-emitting device as set forth in claim 10.

16. A display device comprising the light-emitting device as set forth in claim 11.

17. An electronic apparatus comprising the display device as set forth in claim 13.

18. An electronic apparatus comprising the display device as set forth in claim 14.

19. An electronic apparatus comprising the display device as set forth in claim 15.

20. An electronic apparatus comprising the display device as set forth in claim 16.
